(19) United States
(12) Patent Application Publication
(10) Pub. No.: US 2010/0277185 A1
(43) Pub. Date: Nov. 4, 2010

(54) SOIL MOISTURE SENSOR

(75) Inventor: William C. Hughes, Woodstock, IL (US)

Correspondence Address: K&L Gates LLP, P.O. Box 1135, CHICAGO, IL, 60690, US

(73) Assignee: Spectrum Technologies, Inc., Plainfield, IL (US)

(21) Appl. No.: 12/434,134

(22) Filed: May 1, 2009

(51) Int. Cl. G01R 27/26

(52) U.S. Cl. 324/664

(57) ABSTRACT

A soil moisture probe includes a capacitance-type probe and a detection circuit. The probe includes two spaced electrodes on the same side of a printed circuit board (PCB). The electrodes are placed on an inner layer of a multi-layer PCB and the detection circuit may be placed on an outer layer. The PCB also includes a ground plane. The detection circuit generates a sawtooth or triangular wave which is converted to a DC voltage representative of the moisture content of a soil sample into which the probe is inserted. The unique circuit uses the capacitance of the probe as part of a low-pass filter that distorts an oscillator-generated square wave into a saw-tooth or triangular wave. A resistance component of the low-pass filter is adjustable, allowing tuning of the probe and the circuit as needed.

### BACKGROUND

Embodiments disclosed herein relate to soil science, hydrology and moisture detectors for use in soils, and in particular for a capacitance-based probe and a circuit for detecting moisture in soils, growing media, and other granular or fibrous media which may contain moisture.

Plants require an adequate supply of water to grow well. Water content in media such as soil, sand and soil-less media can control many soil conditions, such as irrigation and fertilization conditions, surface runoff, erosion and salinity.

Accurate measurement of water content in the root zone of plants is becoming ever more important as water resources become more limited in arid regions. As water becomes a more costly resource, growers are forced to cut usage back to the minimum required to grow healthy plants. Proper management of irrigation under these conditions requires measurement of soil moisture in the root zone. If too much water is applied, air is forced out of the soil and hinders root growth along with the obvious waste of water. If too little water is applied, plants become moisture stressed and fail to grow. The plants can even die if the water shortage is significant. If the moisture content of the soil is measured, both of these conditions can be avoided and healthy crops can be produced with a minimal amount of water.

What is needed is a soil moisture sensor that is rugged, portable, and inexpensive, easy to clean, and able to handle a variety of soil samples in sequence. The moisture sensor should not be affected by contamination or traces from previous samples. It should be powered by a low voltage and consume minimal amounts of power when in use.

### SUMMARY

Embodiments described herein include a moisture sensor. The moisture sensor includes a capacitive moisture sensor and a detection circuit for measuring a moisture content of a sample with the capacitive sensor. The detection circuit includes an oscillator, a low-pass filter connected in series with the oscillator, the low pass filter including a resistance, wherein the capacitive sensor forms a part of the low-pass filter. The detection circuit also includes a peak detector connected in series with the low-pass filter. The peak detector includes a diode and a charging circuit, the charging circuit connected in series with an output of the diode, the charging circuit including a resistor and a capacitor, wherein the charging circuit is configured to charge the capacitor and wherein a charge on the capacitor is a function of the moisture content of the sample and an output voltage of the diode.

Another embodiment is a moisture sensor. The moisture sensor includes a capacitive sensor with two electrodes formed on a same side of a printed circuit board and a detection circuit for measuring a moisture content of a soil sample with the capacitive sensor, the detection circuit formed on the printed circuit board. The detection circuit includes an oscillator and a low-pass filter connected in series with the oscillator, the low pass filter including an adjustable resistor, the capacitive sensor connected with an output of the adjustable resistor to form a part of the low-pass filter. The detection circuit also includes a diode connected in series with the low-pass filter and a charging circuit connected with an output of the diode, the charging circuit including a charging capacitor and a resistor, the charging circuit configured to charge the charging capacitor, wherein a charge on the charging capacitor is a function of the moisture content of the soil sample and an output voltage of the diode. The detection circuit also includes optionally a noise filter connected to the power supply.

In one embodiment, the charging circuits used in the moisture detector may include one of (i) a power supply connected to a pull-up resistor and a charging capacitor connected to ground; and (ii) a charging capacitor and a pulldown resistor connected in parallel between the peak detector and ground.

Another embodiment includes a method for detecting moisture in a soil sample. The method includes steps of sensing the sample with a capacitive sensor, generating a high-frequency square wave with an oscillator and sending the square wave through a low-pass filter to form a triangular wave. The method also includes a step of detecting a peak voltage of the triangular with a peak detection circuit, wherein the circuit passes only a DC voltage proportional to the peak voltage of the triangular wave and passing the DC voltage through a peak detector comprising a diode connected to one of (i) a pull-up resistor and charging capacitor; and (ii) a charging capacitor and a pull-down resistor, wherein a charge on the charging capacitor is a function of a moisture content of the soil sample.

Additional features and advantages are described herein, and will be apparent from the following Detailed Description and the figures.

### BRIEF DESCRIPTION OF THE FIGURES

FIG. 1 is a perspective view of an embodiment of the soil moisture sensor.

FIG. 2 depicts a first embodiment of a circuit diagram for operating the soil moisture sensor.

FIGS. 3A-3D depict signal levels at several point in the circuit diagrams of FIG. 2 and FIG. 4.

FIG. 4 depicts a second embodiment of a circuit diagram for operating the soil moisture sensor.

FIGS. 5-6 depict an embodiment of the sensor for the soil moisture sensor.

### DETAILED DESCRIPTION

The present patent discloses and describes our discovery, a soil moisture sensor that uses a capacitance probe. The rugged soil moisture probe described herein may be used with other circuits for generating an electric field and detecting moisture. The remarkable soil moisture circuit described herein may be used with other probes. Together, our new capacitance-based probe and the circuit form an inexpensive, reliable and effective tool for quickly determining a dielectric constant of a soil sample. From this measurement, a soil moisture is easily and readily determined.

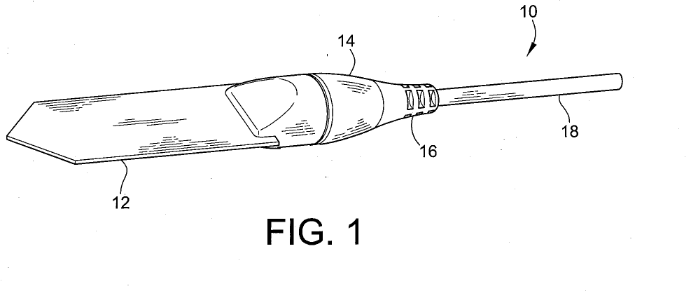

FIG. 1 depicts a soil moisture probe 10 with a capacitance-based sensor 12, a handle 14 with a flexible portion 16 and a cable 18 for use with a moisture readout (not shown). As described herein, the sensor 12 is a multi-layer printed circuit board (PCB) with a suitable moisture-resistant coating. The handle 14 grasps the sensor 12 while protecting the circuitry within the proximal portion of the PCB. The rear portion of the handle may be flexible, allowing a range of movement for the cable. In one embodiment, the handle 14 is relatively stiff and is molded from a suitable thermoplastic material, such as polyamide or nylon, ABS or PVC. Elastomers may also be used, such as urethane or nitrile rubber. The flexible portion may be made from an elastomer or other preferred material. While details are not shown, those with skill in the art will appreciate that all interfaces in the probe 10 will be well sealed, both to prevent ingress of moisture into the handle and also to prevent buildup of soils or other samples on the outside of the sensor 12.

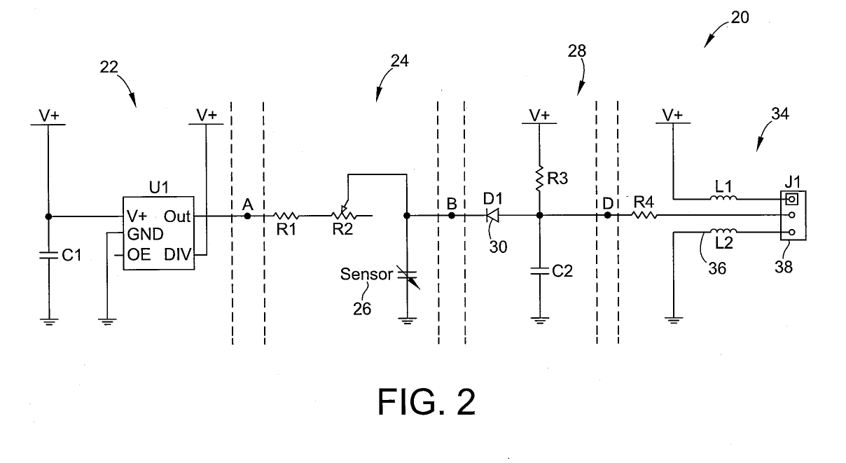

The sensor 12 forms part of the operating circuit depicted in FIG. 2. The operating circuit 20 of FIG. 2 is easily placed on one side of a multi-layer PCB, such as a four-layer or four-surface PCB, used in one embodiment to form the sensor. Circuit 20 includes an oscillator circuit 22 with an oscillator U1. Oscillator U1 in this embodiment runs at about 80 MHz. The circuit includes a 3V power supply and a capacitor C1 as shown. The power sources depicted in FIG. 2 may be supplied from a suitable battery or may alternatively be supplied from a remotely-located power source and routed to the points indicated in the circuit.

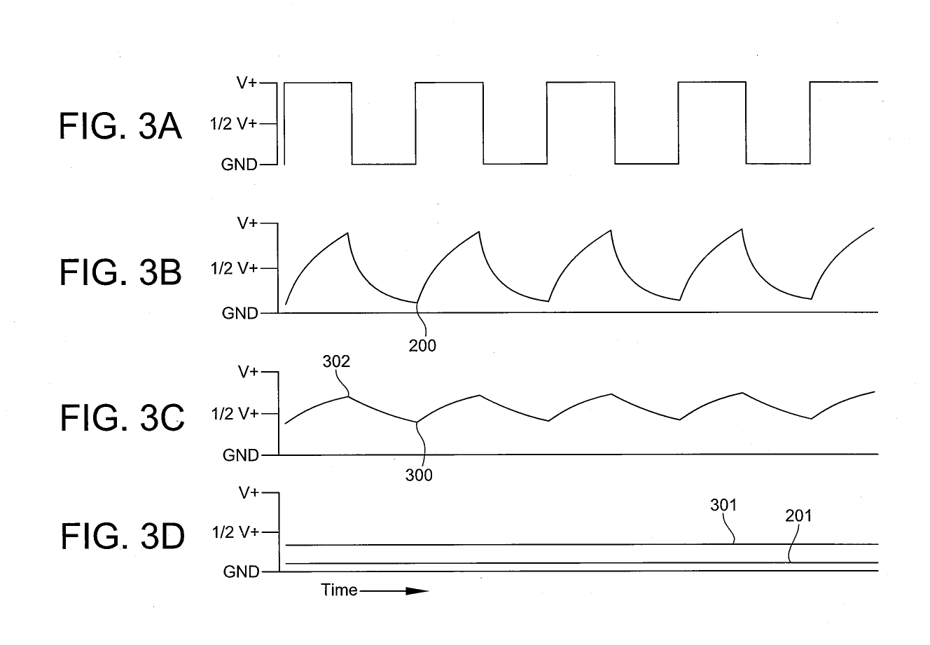

The oscillator generates a square wave and sends the square wave at point A to an RC low-pass filter 24 formed by resistor R1, which may be a precision resistor, variable or adjustable resistor R2, and the capacitor formed by sensor 26. An example of a square wave output by the oscillator at point A is depicted in FIG. 3A. Low-pass filter 24 distorts the square wave into a sawtooth wave at point B, as depicted in FIG. 3B or 3C. FIG. 3B depicts a waveform 200 for a sample that is relatively dry, i.e., very little moisture and very little distortion of the input square wave to the resulting sawtooth wave. In one embodiment, the square wave has a peak-to-peak voltage of about 3 V. FIG. 3C depicts a waveform 300 for a sample that is relatively wet, i.e. greater moisture and greater distortion of the input square wave to the resulting sawtooth or triangle wave.

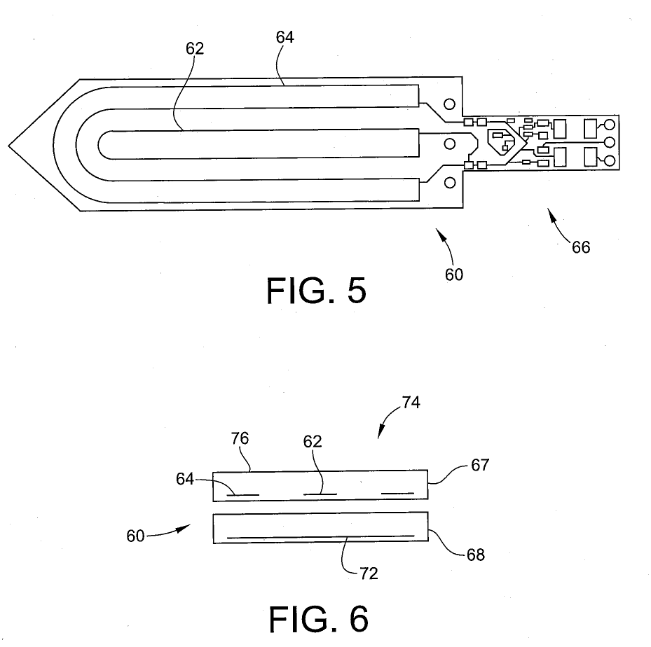

Selection of the values for R1 and R2 are based on the desire to maximize the difference in distortion of the square wave. The difference will be caused by the moisture in the sample and the resultant sensor readings, the frequency of the oscillator, and the capacitance of the sensor electrodes 62 and 64, as shown in FIG. 5. Adjustable resistor R2 allows calibration of the circuit 20 such that each sensor produced will have similar output voltages for given moisture conditions. Due to variations in component specifications and circuit board manufacturing tolerances, this calibration method is desirable to reduce unit to unit variation. Adjustable resistor R2 is not strictly necessary for proper operation of the circuit, but it provides an easy way to increase the accuracy of the sensor.

A larger value of sensor capacitance causes greater distortion of the wave and less peak-to-peak voltage. A lower value of sensor capacitance causes less distortion of the wave and greater peak-to-peak voltage. The capacitance of the probe is of course a function of moisture in the sample, i.e., moisture in the soil sample, with greater capacitance resulting from greater moisture content. As noted, an example of the waveform resulting from a relatively moist sample is depicted in FIG. 3C. In this example, the sawtooth wave of FIG. 3B has been replaced with what might be called a triangular waveform. Those with skill in the art will recognize that the terms used in this disclosure to describe waves, such as square wave, sawtooth waves and triangular waves, are at best approximations. Such waveforms, as seen in FIGS. 3A-3C, vary significantly from the geometric ideal of a square, a sawtooth, or a triangle. However, these are the terms used by people with skill in electronic arts and are intended in that sense. The distorted sawtooth wave may be detected at point B.

The sawtooth wave is then sent to a peak detection circuit 28 for conversion. In the embodiment of FIG. 2, diode D1 has a cathode connected to the sensor capacitor 26 and an anode connected to the output connector 38. When the wave voltage present at point B is greater than the voltage at point D, no current flows through diode D1. When the wave voltage at point B drops below the voltage at point D, diode D1 becomes forward biased and C2 is discharged to through diode D1 until the voltage at point D is equal to the voltage at point B plus the forward voltage of diode D1. As a result, the voltage at point D tracks the lower peak voltage of the wave form present at point B. When the voltage of the wave form at point B is greater then the voltage at point D, resistor R3 adds charge to capacitor C2 so that the charge is removed through D1 when the lowest point of the waveform at point B is reached.

The values of resistor R3 and capacitor C2 are selected such that the amount of charge that can be added to capacitor C2 by resistor R3 is relatively negligible during a single waveform cycle. Thus, there is effectively a DC voltage present at point D, the output of the peak detection circuit. In one embodiment as noted above, the sawtooth wave has a lower peak (or trough) voltage as shown at 300 in FIG. 3C. In the embodiment of FIG. 3D, the output voltage at point D is shown by line 301 for a wet sample and line 201 for a dry sample. Moisture in the sample adds capacitance and damps and distorts the sawtooth wave, converting it to a higher voltage. Thus, the output of the peak detection circuit 28 is proportional to soil moisture.

This signal is then passed through a current-limiting resistor R4 to an output on connector 38 for connection to a readout (not shown). Current limiting resistor R4 stabilizes the signal when long cables are used between the connector 38 and the remote readout. The moisture sensor may also include a close-coupled noise filter 34 connected to the moisture sensor power supply. Noise filter 34 is primarily intended to remove 80 MHz noise from the oscillator that is present in the supply voltage and ground connections in the circuit. Noise filter 34 in one embodiment is a pair of 560 μH inductors 36.

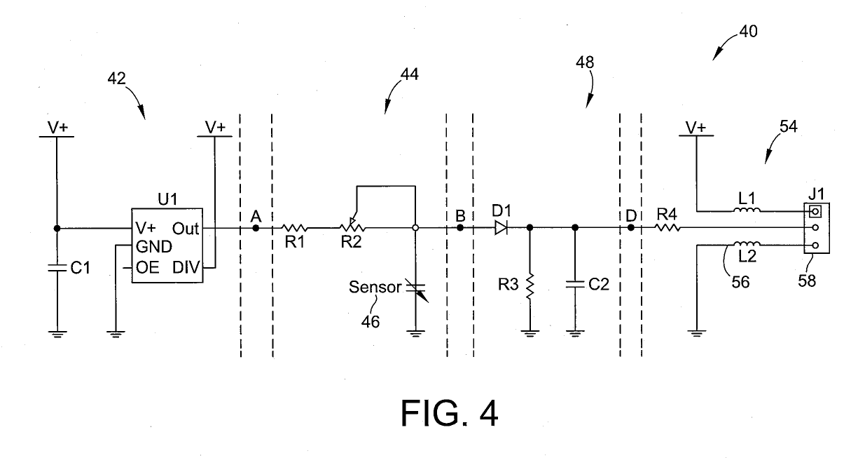

The embodiment of FIG. 2 is only one way of using the capacitance sensor described herein. Another exemplary circuit 40 is depicted in FIG. 4. The circuit of FIG. 4 is very similar to that of FIG. 2, but in FIG. 4, the diode has the anode connected to the sensor capacitor, i.e., reversed from the previous example. In addition, the peak detection circuit uses a pulldown resistor R3 in parallel with capacitor C2. Thus, circuit 40 has a peak detection circuit 48 that measures the higher peak voltage of the waveform present at point B. The higher peak voltage is depicted as peak 302 in FIG. 3C. Therefore, a dry sample will produce a higher output voltage at point B than a wet sample.

This embodiment also includes an oscillator circuit 42 with an oscillator U1, a low-pass RC filter 44, the filter 44 including a fixed resistor R1 (which may be a precision resistor) and a variable resistor R2 in series, and connected to capacitance sensor 46 near point B. Peak detection circuit 48 includes capacitor C2, which is charged through diode D1 during relatively high voltage signals of the waveform at point B. Resistor R3 works to discharge capacitor C2 when diode D1 is reverse biased. The circuit of FIG. 4 works in a way that is similar to the circuit of FIG. 2, but inverted. In FIG. 4, a DC voltage is present at point D, the voltage following the upper peak of the wave form at point B. The remaining portions of circuit 40 are similar, with current-limiter R4, and noise filter 54 with matching coupled inductors 56 and connector 58. It will be understood that noise filter 54 may include other components, such as capacitors. However, close-coupled inductors are relatively small and effective while capacitors may have to be several hundred microfarads, and thus are not convenient for hand-held or portable use.

A capacitance probe useful in the above circuit is depicted in FIGS. 5-6. However, other capacitance sensors may also be used with the circuits described above. In one embodiment, sensor 60 is a four-layer circuit board, that is two pieces of fiberglass and resin having four surfaces, two inner surfaces and two outer surfaces. The sensor includes two electrodes, an inner linear electrode 62 within a larger C-shaped electrode 64. The outer electrode may also be described as a horseshoe electrode. Electrodes 62, 64 in this embodiment are approximately 1 ounce copper or copper alloy (about 0.0014 inches thick) on an FR-4 printed circuit board (PCB) as discussed above with respect to the circuits. Other thicknesses may be used. Other conductive metals or even other materials may be used. As depicted in FIGS. 2 and 4, inner electrode 62 is connected near point B in the circuits, while outer electrode 64 is connected to ground. The circuit board also includes control circuits 66, discussed above with respect to FIGS. 2 and 4.

The spacing between the electrodes is about 0.125 inches (about 3 mm). Inner electrode 62 is a little wider, about 0.170 inches (about 4 mm) and about 1.75 inches (about 4.4 cm) long, while outer electrode 64 is about 0.125 inches wide (about 3 mm) and about twice as long as inner electrode 62. The circuit board is very convenient and portable, with an overall length of about 3 inches (about 8 cm), the wide or electrode portion about 2.65 inches (about 6.7 cm) long. The circuit board in this embodiment is narrow, about 0.75 inches (about 2 cm) wide.

As shown in FIG. 6, sensor 60 includes a multi-layer circuit board with an upper layer 67 having two surfaces and lower layer 68 also having two surfaces. Upper layer 67 depicts inner electrode 62 and outer electrode 64 on a bottom side of the upper layer. Although not shown in FIG. 6, a control circuit, similar to one of FIG. 2 or FIG. 4, is placed on the upper side 76 of upper layer 67 and connects to electrodes 62, 64 via internal connections between the top and bottom sides. Bottom layer 68 includes a ground plane 72 under only the portion of the circuit board containing the control circuit. After fabrication and assembly, the circuit board is coated with a solder resist or other thin, durable coating. This construction allows for convenient mass production of the sensor and the detection circuit. The resulting sensor/control circuit is sensitive to changes in the moisture content of its environment. At the same time, the circuit board is smooth and flat, with no seams, undercuts, or discontinuities in the distal or sensing portion. This makes the sensor easy to keep clean and to avoid interference between successive samples.

There are many embodiments possible with this disclosure. For example, much more complicated ways may be devised to convert the sawtooth or triangular wave representing the output of the low-pass filter and capacitance sensor into a DC voltage. These may include multi-diode rectifiers or converters, op amps, and the like. However, at least one advantage of the present circuit lies in its simplicity, with the resulting reliability and low cost. Another advantage of this design also lies in its adaptability. Since there is inherent variation in manufactured components, adjustment of R2 allows each sensor built to be adjusted to a similar output value and therefore reduces the variation from sensor to sensor.

The electrodes discussed above may also be designed with different configurations. Since the probe is a capacitance probe, there will be two electrodes, forming the plates of a capacitor. There are many other ways of forming and placing the electrodes. The field depth of the electric field set up by the electrodes is somewhat proportional to the gap between the electrodes and may be varied. Thus, greater field depth may be achieved by extending the gap. Greater field depth may also be achieved by increasing the electrode areas for a greater penetration of the field into the soil or sample. There are tradeoffs, of course, since some of these other configurations may require greater power and larger physical size.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

What is claimed is:

1. A moisture sensor, comprising:
a capacitive moisture sensor; and
a detection circuit for measuring a moisture content of a sample with the capacitive sensor, the detection circuit comprising
an oscillator;
a low-pass filter connected in series with the oscillator, the low pass filter including a resistance, wherein the capacitive sensor forms a part of the low-pass filter; and
a peak detector connected in series with the low-pass filter, the peak detector comprising a diode and a charging circuit, the charging circuit connected in series with an output of the diode, the charging circuit comprising a resistor and a capacitor, wherein the charging circuit is configured to charge the capacitor and wherein a charge on the capacitor is a function of the moisture content of the sample and an output voltage of the diode.

2. The moisture sensor according to claim 1, further comprising a current limiting resistor connected in series with the charging circuit.

3. The moisture sensor according to claim 1, further comprising a noise filter comprising two coupled inductors on power supply lines for the moisture sensor.

4. The moisture sensor according to claim 1, wherein the charging circuit comprises one of (i) a power supply connected to a pull-up resistor and a charging capacitor connected to ground; and (ii) a charging capacitor and a pulldown resistor connected in parallel between the peak detector and ground.

5. The moisture sensor according to claim 1, wherein the capacitive moisture sensor comprises a multi-layer printed circuit board with an inner electrode and an outer electrode.

6. The moisture sensor according to claim 1, wherein the capacitive moisture sensor comprises a multi-layer printed circuit board.

7. The moisture sensor according to claim 1, wherein the moisture sensor comprises two electrodes separated by a gap, the electrodes and the detection circuit fabricated on a same circuit board.

8. The moisture sensor according to claim 1, wherein the resistance comprises an adjustable resistor.

9. A moisture sensor, comprising:
a capacitive sensor comprising two electrodes formed on a same side of a printed circuit board; and
a detection circuit for measuring a moisture content of a soil sample with the capacitive sensor, the detection circuit formed on the printed circuit board and comprising
an oscillator;
a low-pass filter connected in series with the oscillator, the low pass filter including an adjustable resistor, the capacitive sensor connected with an output of the adjustable resistor to form a part of the low-pass filter;
a diode connected in series with the low-pass filter; and
a charging circuit connected with an output of the diode, the charging circuit comprising a charging capacitor and a resistor, the charging circuit configured to charge the charging capacitor and wherein a charge on the charging capacitor is a function of the moisture content of the soil sample and an output voltage of the diode.

10. The moisture sensor according to Clam 9, wherein the output of the low pass filter is a generally sawtooth wave.

11. The moisture sensor according to claim 9, further comprising a noise filter connected to a power supply for the moisture sensor.

12. The moisture sensor according to claim 9, wherein the low pass filter comprises the adjustable resistor in series with a resistor or a precision resistor.

13. The moisture sensor according to claim 9, wherein an output of the oscillator and the low-pass filter is a sawtooth or triangular wave and wherein an output of the diode and the charging circuit is a DC voltage whose value depends on the moisture content of the soil sample.

14. The moisture sensor according to claim 9, wherein the noise filter comprises parallel matching inductors for suppressing high frequency noise.

15. The moisture sensor according to claim 9, wherein the capacitive sensor comprises a first rectangular electrode and a second U-shaped electrode enclosing the first electrode.

16. The moisture sensor according to claim 9, wherein a penetration depth of the capacitive sensor is proportional to a gap separating the two electrodes.

17. A method for detecting moisture in a soil sample, the method comprising:
sensing the sample with a capacitive sensor;
generating a high-frequency square wave with an oscillator;
sending the square wave through a low-pass filter to form a triangular wave; and
detecting a peak voltage of the triangular wave with a peak detection circuit wherein the circuit passes only a DC voltage proportional to the peak voltage of the triangular wave and passing the DC voltage through a peak detector comprising a diode connected to one of (i) a pull-up resistor and charging capacitor; and (ii) a charging capacitor and a pull-down resistor, wherein a charge on the charging capacitor is a function of a moisture content of the soil sample.

18. The method according to claim 17, wherein the step of forming the triangular wave is accomplished with an adjustable resistor.

19. The method according to claim 17, wherein the capacitive sensor is configured with a first electrode having a length about twice as long as a second electrode.

20. The method according to claim 17, wherein the capacitive sensor is configured with a gap between a first and a second electrode, the gap having a width about equal to a width of the first and second electrodes.
